(19) United States
(12) Patent Application Publication
(10) Pub. No.: US 2026/0121457 A1
(43) Pub. Date: Apr. 30, 2026

(54) ECOSYSTEM SCALING AND FRIENDLY METAL LOSS ESTIMATION FOR WIRELESS POWER TRANSFER

(71) Applicant: Apple Inc., Cupertino, CA (US)

(72) Inventors: Brandon Russel Marian Pais, Auckland (NZ); Zhao Yuan, San Jose, CA (US)

(21) Appl. No.: 19/302,391

(22) Filed: Aug. 18, 2025

Related U.S. Application Data
(60) Provisional application No. 63/713,288, filed on Oct. 29, 2024.

(51) Int. Cl. H02J 50/60; G01R 21/133; G01V 3/10; H02J 50/10

(52) U.S. Cl. CPC H02J 50/60; G01R 21/133; G01V 3/10; H02J 50/10

(57) ABSTRACT

Estimating friendly metal losses (P_{FM}) associated with power transfer from a wireless power transmitter (PTx) to a wireless power receiver (PRx) can include determining P_{FM} based on one or more circuit parameters; subtracting an effect of one or more voltage or current measurements from the determined P_{FM} to derive a modified P_{FM}; and determining ecosystem scaling parameters based on the modified P_{FM}. The ecosystem scaling parameters can include scale factors based on operation of the PTx with a reference PRx; operation of the PRx with a reference PTx; and/or operation of the reference PRx with the reference PTx. Estimating P_{FM} can further include adding the effect of at least one of the one or more voltage or current measurements from the determined P_{FM} to derive one or more loss coefficients; and performing foreign object detection based on a P_{FM} model including the derived loss coefficients.

### CROSS-REFERENCE TO RELATED APPLICATIONS

This application claims benefit of Applicant's co-pending U.S. Provisional Patent Application 63/713,288, entitled “Ecosystem Scaling and Friendly Metal Loss Estimation for Wireless Power Transfer”, filed Oct. 29, 2024, which is hereby incorporated by reference in its entirety, including all references incorporated therein. This application is also related to Applicant's co-pending U.S. patent application Ser. No. 19/088,356, entitled “Friendly Metal Loss Estimation for Wireless Power Transfer”, filed Mar. 24, 2025, which claims benefit of U.S. Provisional Patent Application 63/637,184, entitled “Friendly Metal Loss Estimation for Wireless Power Transfer”, filed Apr. 22, 2024, both of which are hereby incorporated by reference in their entirety, including all references incorporated therein.

### BACKGROUND

Wireless power transfer is used in various electronic devices. For example, smart phones, tablet computers, smart watches, wireless earphones, styluses, etc. may employ wireless power transfer to facilitate charging of batteries within the devices. In some application, higher levels of wireless power transfer may be desired, for example to provide for faster charging. Such higher power transfer levels can benefit from techniques to improve estimation of losses, including losses associated with “friendly metal” associated with a wireless power transmitter and/or wireless power receiver device.

### SUMMARY

A method performed by control circuitry of a wireless power transmitter or a wireless power receiver for estimating friendly metal losses associated with wireless power transfer from the wireless power transmitter to a wireless power receiver can include obtaining one or more circuit parameters including one or more voltage or current measurements of the wireless power transmitter or the wireless power receiver; determining friendly metal losses based on the one or more circuit parameters; subtracting an effect of at least one of the one or more voltage or current measurements from the determined friendly metal losses to derive a modified friendly metal loss; determining one or more ecosystem scaling parameters based on the modified friendly metal loss; adding the effect of at least one of the one or more voltage or current measurements from the determined friendly metal losses to derive one or more friendly metal loss coefficients; and performing foreign object detection based on a friendly metal loss model including the derived one or more friendly metal loss coefficients.

The one or more ecosystem scaling parameters can be based one or more of operation of the wireless power transmitter with a reference wireless power receiver; operation of the wireless power receiver with a reference wireless power transmitter; and operation of the reference wireless power transmitter with the reference wireless power receiver. The one or more circuit parameters can include a rectifier voltage of the wireless power receiver, a rectifier current of the wireless power receiver, and an inverter voltage of the wireless power transmitter. Subtracting the effect of at least one of the one or more voltage or current measurements from the determined friendly metal losses to derive a modified friendly metal loss can include subtracting an effect of the rectifier current. The derived one or more friendly metal loss coefficients can include a first coefficient relating to the rectifier current, a second coefficient relating to the rectifier voltage, and a third coefficient relating to the transmitter current. The friendly metal power loss model can be of the form:

$${P}_{loss} = a \cdot {I}_{TX}^{2} + b \cdot {I}_{rect}^{2} + c \cdot {V}_{rect}^{2}$$

where b is the first coefficient relating to the rectifier current, c is the second coefficient relating to the rectifier voltage, and a is the third coefficient relating to transmitter current.

A wireless power transmitter can include a wireless power transmitter coil configured to magnetically couple to a wireless power receiver coil of a wireless power receiver to wirelessly transfer power to the wireless power receiver; an inverter configured to receive input power and generate an output that drives the wireless power transmitter coil; and controller and communication circuitry coupled to the inverter and the wireless power transmitter coil that controls the inverter to regulate wireless power transfer to the wireless power receiver. The controller and communication circuitry can estimate a friendly metal loss associated with wireless power transfer to the wireless power receiver by obtaining one or more circuit parameters including one or more voltage or current measurements of the wireless power transmitter or the wireless power receiver; determining friendly metal losses based on the one or more circuit parameters; subtracting an effect of at least one of the one or more voltage or current measurements from the determined friendly metal losses to derive a modified friendly metal loss; determining one or more ecosystem scaling parameters based on the modified friendly metal loss; adding the effect of at least one of the one or more voltage or current measurements from the determined friendly metal losses to derive one or more friendly metal loss coefficients; and performing foreign object detection based on a friendly metal loss model including the derived one or more friendly metal loss coefficients.

The one or more ecosystem scaling parameters can be based one or more of operation of the wireless power transmitter with a reference wireless power receiver; operation of the wireless power receiver with a reference wireless power transmitter; and operation of the reference wireless power transmitter with the reference wireless power receiver. The one or more circuit parameters can include a rectifier voltage of the wireless power receiver, a rectifier current of the wireless power receiver, and an inverter voltage of the wireless power transmitter. Subtracting the effect of at least one of the one or more voltage or current measurements from the determined friendly metal losses to derive a modified friendly metal loss can include subtracting an effect of the rectifier current. The derived one or more friendly metal loss coefficients can include a first coefficient relating to the rectifier current, a second coefficient relating to the rectifier voltage, and a third coefficient relating to the transmitter current. The friendly metal power loss model can be of the form:

$${P}_{loss} = a \cdot {I}_{TX}^{2} + b \cdot {I}_{rect}^{2} + c \cdot {V}_{rect}^{2}$$

where b is the first coefficient relating to the rectifier current, c is the second coefficient relating to the rectifier voltage, and a is the third coefficient relating to transmitter current.

A wireless power receiver can include a wireless power receiver coil configured to magnetically couple to a wireless power transmitter coil of a wireless power transmitter to wirelessly receive power from the wireless power receiver; a rectifier configured to receive input power from the wireless power receiver coil and generate an output that delivers power to a load; and controller and communication circuitry coupled to the rectifier and the wireless power receiver coil that controls the rectifier and estimates a friendly metal loss associated with wireless power transfer to the wireless power receiver by: obtaining one or more circuit parameters including one or more voltage or current measurements of the wireless power transmitter or the wireless power receiver; determining friendly metal losses based on the one or more circuit parameters; subtracting an effect of at least one of the one or more voltage or current measurements from the determined friendly metal losses to derive a modified friendly metal loss; determining one or more ecosystem scaling parameters based on the modified friendly metal loss; adding the effect of at least one of the one or more voltage or current measurements from the determined friendly metal losses to derive one or more friendly metal loss coefficients; and performing foreign object detection based on a friendly metal loss model including the derived one or more friendly metal loss coefficients.

Subtracting the effect of at least one of the one or more voltage or current measurements from the determined friendly metal losses to derive a modified friendly metal loss can include subtracting an effect of the rectifier current. The derived one or more friendly metal loss coefficients can include a first coefficient relating to the rectifier current, a second coefficient relating to the rectifier voltage, and a third coefficient relating to the transmitter current. The friendly metal power loss model can be of the form:

$${P}_{loss} = a \cdot {I}_{TX}^{2} + b \cdot {I}_{rect}^{2} + c \cdot {V}_{rect}^{2}$$

where b is the first coefficient relating to the rectifier current, c is the second coefficient relating to the rectifier voltage, and a is the third coefficient relating to transmitter current.

### BRIEF DESCRIPTION OF THE DRAWINGS

FIG. 1 illustrates a simplified block diagram of a wireless power transfer system.

FIGS. 2A-2B illustrate a circuit model and associated equations of a wireless power transfer system.

FIG. 3 illustrates aspects of an ecosystem scaling arrangement for a wireless power transfer system.

FIG. 4 illustrates some combinations of monitorable parameters in a wireless power transfer system that can be used for friendly metal loss estimation.

FIG. 5 illustrates aspects of an ecosystem scaling arrangement for a wireless power transfer system.

FIG. 6 illustrates a flowchart of an ecosystem scaling arrangement for a wireless power transfer system.

### DETAILED DESCRIPTION

In the following description, for purposes of explanation, numerous specific details are set forth to provide a thorough understanding of the disclosed concepts. As part of this description, some of this disclosure's drawings represent structures and devices in block diagram form for sake of simplicity. In the interest of clarity, not all features of an actual implementation are described in this disclosure. Moreover, the language used in this disclosure has been selected for readability and instructional purposes, has not been selected to delineate or circumscribe the disclosed subject matter. Rather the appended claims are intended for such purpose.

Various embodiments of the disclosed concepts are illustrated by way of example and not by way of limitation in the accompanying drawings in which like references indicate similar elements. For simplicity and clarity of illustration, where appropriate, reference numerals have been repeated among the different figures to indicate corresponding or analogous elements. In addition, numerous specific details are set forth to provide a thorough understanding of the implementations described herein. In other instances, methods, procedures, and components have not been described in detail so as not to obscure the related relevant function being described. References to “an,” “one,” or “another” embodiment in this disclosure are not necessarily to the same or different embodiment, and they mean at least one. A given figure may be used to illustrate the features of more than one embodiment, or more than one species of the disclosure, and not all elements in the figure may be required for a given embodiment or species. A reference number, when provided in a given drawing, refers to the same element throughout the several drawings, though it may not be repeated in every drawing. The drawings are not to scale unless otherwise indicated, and the proportions of certain parts may be exaggerated to better illustrate details and features of the present disclosure.

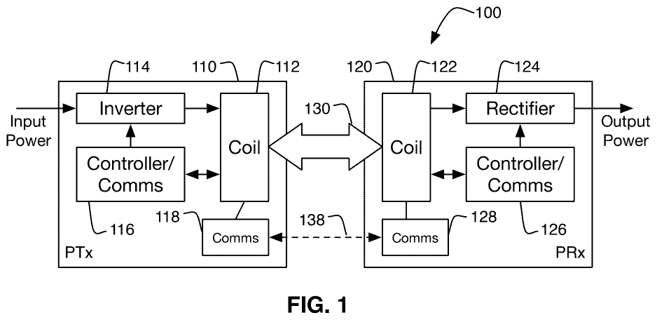

FIG. 1 illustrates a simplified block diagram of a wireless power transfer system 100. Wireless power transfer system includes a power transmitter (PTx) 110 that transfers power to a power receiver (PRx) 120 wirelessly, such as via inductive coupling 130. Power transmitter 110 may receive input power that is converted to an AC voltage having particular voltage and frequency characteristics by an inverter 114. Inverter 114 may be controlled by a controller/communications module 116 that operates as further described below. In various embodiments, the inverter controller and communications module may be implemented in a common system, such as a system based on a microprocessor, microcontroller, or the like. In other embodiments, the inverter controller may be implemented by a separate controller module and communications module that have a means of communication between them. Inverter 114 may be constructed using any suitable circuit topology (e.g., full bridge, half bridge, etc.) and may be implemented using any suitable semiconductor switching device technology (e.g., MOSFETs, IGBTs, etc. made using silicon, silicon carbide, or gallium nitride devices).

Inverter 114 may deliver the generated AC voltage to a transmitter coil 112. In addition to a wireless coil allowing magnetic coupling to the receiver, the transmitter coil block 112 illustrated in FIG. 1 may include tuning circuitry, such as additional inductors and capacitors, that facilitate operation of the transmitter in different conditions, such as different degrees of magnetic coupling to the receiver, different operating frequencies, etc. The wireless coil itself may be constructed in a variety of different ways. In some embodiments, the wireless coil may be formed as a winding of wire around a suitable bobbin. In other embodiments, the wireless coil may be formed as traces on a printed circuit board. Other arrangements are also possible and may be used in conjunction with the various embodiments described herein. The wireless transmitter coil may also include a core of magnetically permeable material (e.g., ferrite) configured to affect the flux pattern of the coil in a way suitable to the particular application. The teachings herein may be applied in conjunction with any of a wide variety of transmitter coil arrangements appropriate to a given application.

PTx controller/communications module 116 may monitor the transmitter coil and use information derived therefrom to control the inverter 114 as appropriate for a given situation. For example, controller/communications module may be configured to cause inverter 114 to operate at a given frequency or output voltage depending on the particular application. In some embodiments, the controller/communications module may be configured to receive information from the PRx device and control inverter 114 accordingly. This information may be received via the power transmission coils (i.e., in-band communication) or may be received via a separate communications channel (not shown, i.e., out-of-band communication). For in-band communication, controller/communications module 116 may detect and decode signals imposed on the magnetic link (such as voltage, frequency, or load variations) by the PRx to receive information and may instruct the inverter to modulate the delivered power by manipulating various parameters of the generated voltage (such as voltage, frequency, etc.) to send information to the PRx. In some embodiments, controller/communications module may be configured to employ frequency shift keying (FSK) communications, in which the frequency of the inverter signal is modulated, to communicate data to the PRx. Controller/communications module 116 may be configured to detect amplitude shift keying (ASK) communications or load modulation-based communications from the PRx. In either case, the controller/communications module 126 may be configured to vary the current drawn on the receiver side to manipulate the waveform seen on the Tx coil to deliver information from the PRx to the PTx. For out-of-band communication, additional modules that allow for communication between the PTx and PRx may be provided, for example, WiFi, Bluetooth, or other radio links or any other suitable communications channel.

As mentioned above, controller/communications module 116 may be a single module, for example, provided on a single integrated circuit, or may be constructed from multiple modules/devices provided on different integrated circuits or a combination of integrated and discrete circuits having both analog and digital components. The teachings herein are not limited to any particular arrangement of the controller/communications circuitry.

PTx device 110 may optionally include other systems and components, such as a separate communications module 118. In some embodiments, comms module 118 may communicate with a corresponding module tag in the PRx via the power transfer coils. In other embodiments, comms module 118 may communicate with a corresponding module using a separate physical channel 138.

As noted above, wireless power transfer system also includes a wireless power receiver (PRx) 120. Wireless power receiver can include a receiver coil 122 that may be magnetically coupled 130 to the transmitter coil 112. As with transmitter coil 112 discussed above, receiver coil block 122 illustrated in FIG. 1 may include tuning circuitry, such as additional inductors and capacitors, that facilitate operation of the transmitter in different conditions, such as different degrees of magnetic coupling to the receiver, different operating frequencies, etc. The wireless coil itself may be constructed in a variety of different ways. In some embodiments, the wireless coil may be formed as a winding of wire around a suitable bobbin. In other embodiments, the wireless coil may be formed as traces on a printed circuit board. Other arrangements are also possible and may be used in conjunction with the various embodiments described herein. The wireless receiver coil may also include a core of magnetically permeable material (e.g., ferrite) configured to affect the flux pattern of the coil in a way suitable to the particular application. The teachings herein may be applied in conjunction with any of a wide variety of receiver coil arrangements appropriate to a given application.

Receiver coil 122 outputs an AC voltage induced therein by magnetic induction via transmitter coil 112. This output AC voltage may be provided to a rectifier 124 that provides a DC output power to one or more loads associated with the PRx device. Rectifier 124 may be controlled by a controller/communications module 126 that operates as further described below. In various embodiments, the rectifier controller and communications module may be implemented in a common system, such as a system based on a microprocessor, microcontroller, or the like. In other embodiments, the rectifier controller may be implemented by a separate controller module and communications module that have a means of communication between them. Rectifier 124 may be constructed using any suitable circuit topology (e.g., full bridge, half bridge, etc.) and may be implemented using any suitable semiconductor switching device technology (e.g., MOSFETs, IGBTs, etc. made using silicon, silicon carbide, or gallium nitride devices).

PRx controller/communications module 126 may monitor the receiver coil and use information derived therefrom to control the rectifier 124 as appropriate for a given situation. For example, controller/communications module may be configured to cause rectifier 124 to operate provide a given output voltage depending on the particular application. In some embodiments, the controller/communications module may be configured to send information to the PTx device to effectively control the power delivered to the receiver. This information may be received sent via the power transmission coils (i.e., in-band communication) or may be sent via a separate communications channel (not shown, i.e., out-of-band communication). For in-band communication, controller/communications module 126 may, for example, modulate load current or other electrical parameters of the received power to send information to the PTx. In some embodiments, controller/communications module 126 may be configured to detect and decode signals imposed on the magnetic link (such as voltage, frequency, or load variations) by the PTx to receive information from the PTx. In some embodiments, controller/communications module 126 may be configured to receive frequency shift keying (FSK) communications, in which the frequency of the inverter signal has been modulated to communicate data to the PRx. Controller/communications module 126 may be configured to generate amplitude shift keying (ASK) communications or load modulation-based communications from the PRx. In either case, the controller/communications module 126 may be configured to vary the current drawn on the receiver side to manipulate the waveform seen on the Tx coil to deliver information from the PRx to the PTx. For out-of-band communication, additional modules that allow for communication between the PTx and PRx may be provided, for example, WiFi, Bluetooth, or other radio links or any other suitable communications channel.

As mentioned above, controller/communications module 126 may be a single module, for example, provided on a single integrated circuit, or may be constructed from multiple modules/devices provided on different integrated circuits or a combination of integrated and discrete circuits having both analog and digital components. The teachings herein are not limited to any particular arrangement of the controller/communications circuitry. PRx device 120 may optionally include other systems and components, such as a communications (“comms”) module 128. In some embodiments, comms module 128 may communicate with a corresponding module in the PTx via the power transfer coils. In other embodiments, comms module 128 may communicate with a corresponding module or tag using a separate physical channel 138.

Numerous variations and enhancements of the above-described wireless power transmission system 100 are possible, and the following teachings are applicable to any of such variations and enhancements.

In some applications, it may be desirable to increase the rate of power transfer from a wireless power transmitter to a wireless power receiver. One approach to achieve this can be the use of a magnetic power profile (“MPP”) as described beginning in the Qi 2.0 specification promulgated by the Wireless Power Consortium (“WPC”). MPP can employ magnets to provide for improved alignment between the respective wireless power transfer coils of the wireless power transmitter and wireless power receiver. This improved alignment can be one aspect of facilitating higher levels of power transfer. Another aspect of achieving higher levels of power transfer can include improved techniques for foreign object detection and the losses associated therewith. In some cases, the presence of a foreign object near the wireless power transmitter and/or receiver can absorb power and lead to undesired heating of the foreign object. Mitigating these effects can be based on power loss accounting (“PLA”) techniques, in which comparisons between the power transmitted by the wireless power transmitter, the power received by the wireless power receiver can be used to determine power losses associated with the wireless power transfer.

By modeling expected losses for a given wireless power transfer level, the presence of a foreign object may be inferred if the actual losses being experienced exceed the expected losses by some threshold amount. Expected losses can come from a variety of sources, including losses associated with the circuitry of the wireless power transmitter and/or receiver, “friendly metal” in the housings or other structures of the wireless power transmitter and/or receiver, etc. In cases where the actual losses experienced (e.g., measured) exceed the expected level based on modeling, mitigation techniques can be employed, such as reducing or stopping power transfer, providing an audio or visual indication (or other feedback) to a user, etc. Exemplary friendly metal loss modeling and estimation techniques are described in Applicant's co-pending U.S. patent application Ser. No. 18/166,839, entitled “Friendly Metal Loss Estimation,” filed Feb. 9, 2023, which is incorporated by reference in its entirety.

Described herein are improved MPP Power Loss Accounting (MPLA) techniques that can be employed to improve the accuracy of expected loss estimation. MPLA as defined in the Qi v2.0 specification made assumptions on the modelling of friendly metal losses (P_{FM}) in the wireless power system. To improve the accuracy, a new model for friendly metal loss is proposed to account for variations in rectified voltage and current. Additionally, improved ecosystem scaling arrangements can be provided that can allow for use of improved models without unduly perturbing sensitivity of the improved model to particular parameters or measurements.

### Updated MPLA

At a basic level, MPLA power loss estimation begins with estimating power delivered to a foreign object by estimating the difference between the power transmitted by the wireless power transmitter and the power received by a wireless power receiver. In at least some embodiments, this comparison can be performed by controller circuitry located in the wireless power transmitter, although it may be possible in some embodiments for this comparison to be performed by controller circuitry located in the wireless power receiver. In either case, the comparison can be expressed by the following equation:

$${P}_{FO} = {P}_{PT} - {P}_{PR} \qquad ( 1 )$$

where P_{FO} is the power dissipated in a foreign object, P_{PT} is power transmitted by the wireless power transmitter, and P_{PR} is power received by the wireless power receiver. Furthermore, power transmitted by the wireless power transmitter can be expressed as:

$${P}_{PT} = {V}_{IN} {I}_{IN} - {P}_{circuit loss , TX} - {P}_{coil loss , TX} - {P}_{FM loss} \qquad ( 2 )$$

where V_{IN} and I_{IN} are the input voltage and current of the inverter of the wireless power transmitter, P_{circuit} loss, TX represents circuit losses associated with the wireless power transmitter circuitry, P_{coil} loss, TX represents losses associated with the wireless power transmitter coil, and P_{FM} loss represents losses associated with friendly metal of the wireless power transmitter. As noted above, “friendly metal” includes metallic or other conductive structures associated with the wireless power transmitter and receiver devices themselves, such as housing(s), internal structures, etc. Similarly, power received by the wireless power receiver can be expressed as:

$${P}_{PR} = {V}_{RECT} {I}_{RECT} + {P}_{circuit loss , RX} + {P}_{coil loss , RX} \qquad ( 3 )$$

where V_{RECT} and I_{RECT} are the output voltage and current of the rectifier of the wireless power receiver, P_{circuit} loss, RX represents circuit losses associated with the wireless power receiver circuitry, P_{coil loss, RX} represents losses associated with the wireless power receiver coil.

In some applications, various improvements to wireless power transfer can be achieved by varying the rectifier voltage V_{RECT}, i.e., the output voltage of the rectifier 124 in the wireless power receiver. In such cases, it may be desirable to expand the friendly metal loss term, P_{FM loss}, to account for variability in the rectified voltage and current (V_{RECT} and I_{RECT}). For example, the friendly metal loss can be expressed as:

$${P}_{FM loss} = {g}_{FM , ITX} {α}_{FM , ITX} {I}_{TX}^{2} + {g}_{FM , IRECT} {α}_{FM , IRECT} {I}_{RECT}^{2} + {g}_{FM , VRECT} {α}_{FM , VRECT} {V}_{RECT}^{2} \qquad ( 4 )$$

where g_{FM,ITX}, g_{FM,IRECT}, and g_{FM,VRECT} are ecosystem scaling terms (as described in greater detail below), and α_{FM,ITX}, α_{FM,IRECT}, and α_{FM,VRECT} are coefficients relating to the electrical and magnetic circuit parameters (physical and/or equivalent) that characterize the wireless power transfer system. Such coefficients can be described in a variety of ways, some of which are described in greater detail herein. Stated more generally, the friendly metal losses can be modelled in the form:

$${P}_{FM} = a \cdot {I}_{TX}^{2} + b \cdot {I}_{RECT}^{2} + c \cdot {V}_{RECT}^{2} \qquad ( 5 )$$

where P_{FM} are the estimated friendly metal losses, I_{TX} is the DC current into the inverter of the wireless power transmitter, I_{RECT} is the DC current out of the rectifier of the wireless power receiver, and V_{RECT} is the DC output voltage of the rectifier of the wireless power receiver, with a, b, and c being fit coefficients that characterize the particular wireless power transfer system. The above-described model does not require a DC bias term as in some prior power loss accounting techniques.

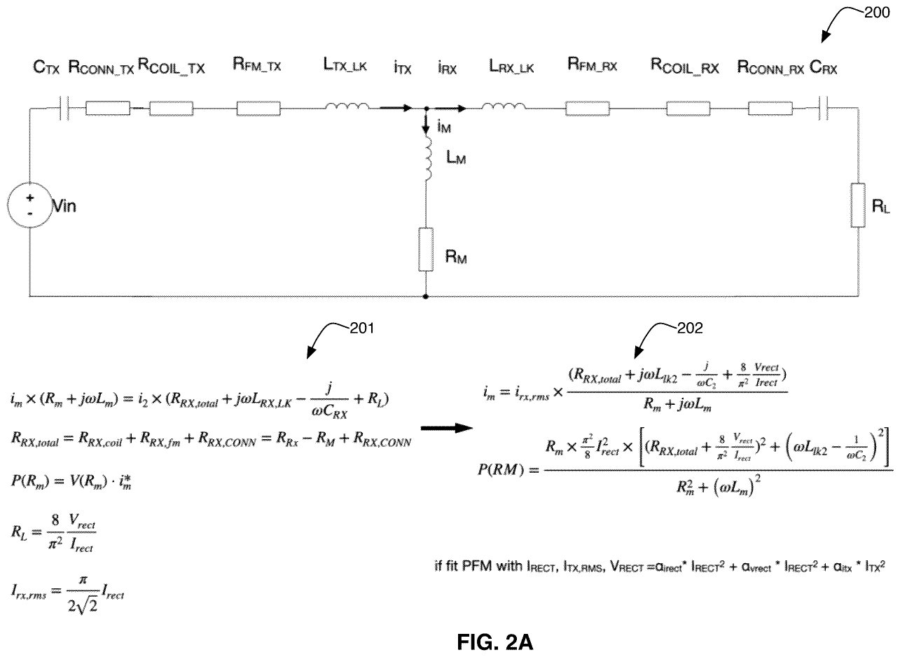

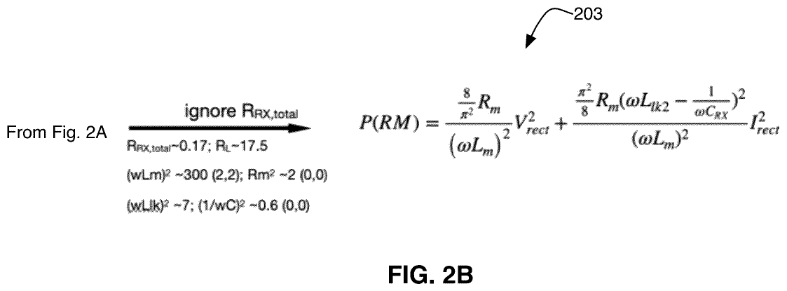

FIGS. 2A and 2B illustrate a derivation of the above-described model. More specifically, FIG. 2A depicts an equivalent circuit 200 that can be used to model the wireless power transfer system. In equivalent circuit 200, the inverter input voltage is represented by voltage source Vin, and the load on the wireless power receiver is represented by resistance R_{L}. The wireless power transmitter current i_{TX} flows through: capacitance C_{TX}, representing the tuning capacitance of the wireless power transmitter; resistance R_{CONN_TX}, representing conduction losses associated with the wireless power transmitter circuitry; resistance R_{COIL_TX}, representing losses in the wireless power transmitter coil; resistance REM TX, representing friendly metal losses associated with metallic or other conductive structures in the wireless power transmitter; and inductance L_{TX_LK}, representing leakage inductance of the wireless power transmitter coil. Wireless power transmitter current i_{TX} can then be modelled as splitting into magnetizing current i_{M} and receiver current i_{RX}. Magnetizing current i_{M} flows through inductance Ly and resistance R_{M} representing the magnetization effects of the wireless power transfer coils. Receiver current i_{RX} flows through inductance L_{RX_LK}, representing leakage inductance of the wireless power receiver coil; REM RX, representing friendly metal losses associated with metallic or other conductive structures in the wireless power receiver; R_{COIL_RX}, representing losses in the wireless power receiver coil; resistance R_{CONN_RX}, representing conduction losses associated with the wireless power receiver circuitry; and capacitance C_{RX}, representing the tuning capacitance of the wireless power receiver. Rather than particular physical devices, the above-described circuit elements may be representative such devices and/or may be lumped parameters representing or modelling multiple physical components or structures.

With further reference to FIG. 2A, equations 201 describe interrelationships between the various circuit elements and parameters of the equivalent circuit model 200. These equations may be combined to produce equations 202. Then, with further reference to FIG. 2B, the equations may be further manipulated to produce equation 203, which expresses the losses in terms of

$${V}_{RECT}^{2} and {I}_{RECT}^{2}$$

which is similar to the form of equations 4 and 5, above.

While the above description models friendly metal losses in terms of transmitter current squared

$$( {I}_{TX}^{2} ) ,$$

receiver rectifier voltage squared

$$( {V}_{RECT}^{2} ) ,$$

and receiver rectifier current squared

$$( {I}_{RECT}^{2} ) ,$$

such losses may be modelled in other ways based on other orders of such variables, such as transmitter current (I_{TX}), rectifier voltage (V_{RECT}), and rectifier current (I_{RECT}) and/or may be modelled in conjunction with other voltages, currents, or other circuit parameters. Further aspects of power loss accounting in terms of rectifier voltage V_{RECT} and rectifier current I_{RECT} are described in Applicant's co-pending U.S. patent application Ser. No. 18/617,103, entitled “Power Transfer Accounting for Wireless Power Transfer,” filed Mar. 26, 2024, which is incorporated by reference in its entirety.

### Ecosystem Scaling

Friendly metal loss estimation as described above may rely on measurements that may be different for each possible wireless power transmitter and wireless power receiver pair. In some cases, multiple such baseline values can be determined, e.g., at manufacture, and stored in a wireless power transmitter (and/or wireless power receiver) as described above. However, as the number of potential transmitter-receiver pairs becomes larger, this may quickly become impracticable. Thus, it may be desired to provide for each transmitter one or more baseline value pairs based on one or more “reference” or “golden” receiver pairings. Similarly, it may be desired to provide for each receiver one or more baseline value pairs based on one or more “reference” or “golden” transmitter pairings. Then, each receiver (or transmitter) can be characterized relative to one or more of the reference/golden receivers (or transmitters) and can be provided with its own stored values corresponding to such characterization. For example, this could be implemented as a variety of scaling factors relative to the reference/golden receiver(s) (or transmitter(s)). Then, a wireless power receiver (or transmitter) could provide its scale factors to the wireless power transmitter (or receiver), which could then calculate appropriate baseline mated-Q and resonant frequency values based on the stored reference values and the scaling factors. Exemplary techniques for loss measurement scaling are described in Applicant's U.S. patent application Ser. No. 17/681,363, entitled “Wireless Power Systems with Shared Inducive Loss Scaling Factors,” filed Feb. 25, 2022, which is incorporated by reference herein in its entirety.

As described above, FIG. 1 shows an illustrative wireless power transfer system 100 in an illustrative scenario in which a wireless power transmitter 110 has been paired with a wireless power receiver 112. The wireless power circuitry of FIG. 1 can include wireless power transmitting circuitry in wireless power transmitter 110 and wireless power receiving circuitry in wireless power receiver 120. During operation, wireless power signals 130 can transmitted by wireless power transmitting circuitry and can be received by wireless power receiving circuitry. The configuration of FIG. 1 includes a single transmitting coil 112 and a single receiving coil 122 (as an example).

As shown in FIG. 1, the wireless power transmitting circuitry can include an inverter 114. Inverter 114 may be used to provide signals to wireless power transmitter coil 112. During wireless power transmission, the control circuitry 116 of wireless power transmitter 110 can supply signals to control inverter 114 so as to cause inverter 114 to supply alternating-current drive signals to wireless power transmitter coil 112. Measurement circuitry in wireless power transmitter 110 may make measurements on operating currents and voltages in wireless power transmitter 110.

When alternating-current current signals are supplied to wireless power transmitter coil 112, corresponding alternating-current electromagnetic signals (wireless power signals 130) can be transmitted to nearby coils such as wireless power receiver coil 122 in wireless power receiver 120. This can induce a corresponding alternating-current (AC) current signal in wireless power receiver coil 122. Rectifier 124 can receive the AC current from wireless power receiver coil 122 and can produce corresponding direct-current power (e.g., a direct-current voltage Vrect) at the output of the wireless power receiver. This power may be used to power a load. Measurement circuitry in wireless power receiver 120 may make measurements on operating currents and voltages in device wireless power receiver 124.

The measurements made by the measurement circuitry may be processed to extract electrical and/or magnetic loss properties (e.g., coefficients or other parameters that characterize the amount of power losses in wireless power transmitter 110 and/or wireless power receiver 120 and that are dependent on the magnetic properties of the transmitter and receiver). These measurements may be stored within each device and may be exchanged between devices so that wireless power transmitter 110 (and, if desired, wireless power receiver 120) may use this information in accurately estimating power losses that might be present due to friendly metal, foreign objects, etc.

In an ecosystem in which there are multiple different models of wireless power transmitting devices available to a user and/or multiple different models of wireless power receiving devices (e.g., different models of either device), the electrical and/or magnetic loss parameters can vary as a function of which particular wireless power transmitter and wireless power receiver are paired together. If, as an example, a model I transmitter and model J receiver are paired, the amount of power loss in each device will differ from that experienced when these devices are paired with different devices.

To account for these variations and thereby ensure accurate estimation of friendly metal, foreign object, and/or other losses, electrical and magnetic power loss parameter scaling factors (sometimes referred to as power loss coefficient scaling factors) can be used. By using such scaling factors in computing various parameters, the loss equations can be satisfactorily evaluated regardless of which models of transmitter and receiver are paired with each other. Exchange of such scaling parameters between various wireless power transfer devices may be thought of as providing for “ecosystem scaling” in that it expands the “ecosystem” of devices that can cooperate to provide wireless power transfer and foreign object detection. Such ecosystem scaling can be extended to the context friendly metal loss estimation described above.

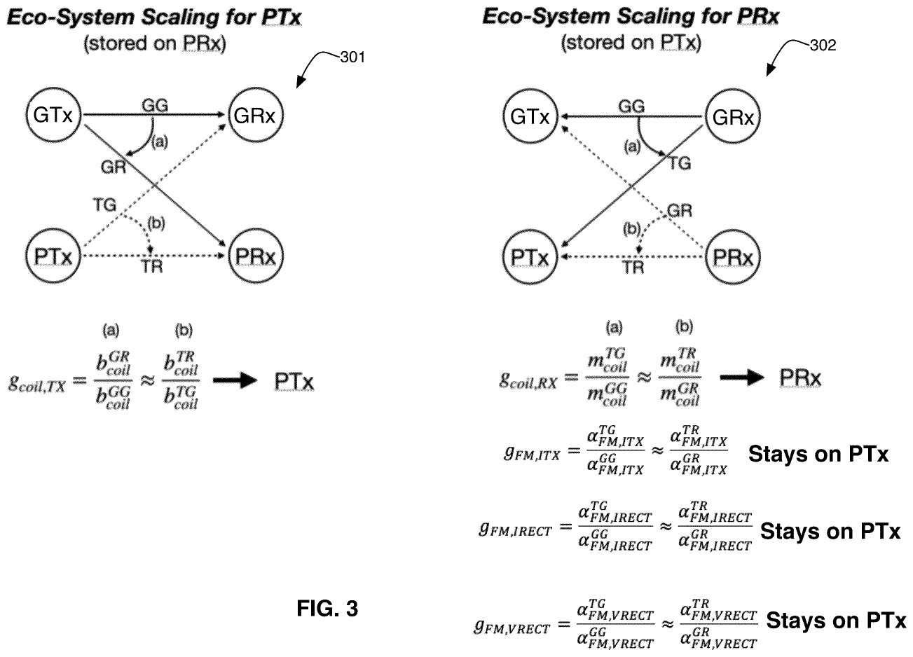

The basic procedure to perform ecosystem scaling for friendly metal loss estimation can include various aspects depicted in FIG. 3. Beginning with diagram 301 of FIG. 3, on the wireless power transmitter (PTx) side, various gain factors g may be computed for various parameters based on parings between a “golden” or “reference” wireless power transmitter GTx and wireless power receiver GRx and the actual wireless power transmitter PTx and wireless power receiver PRx. More specifically, scaling or proportionality factors (a) can be used to scale a measurement GG as between the golden or reference transmitter GTx and golden or reference receiver GRx so as to correspond to a measurement GR as between the golden transmitter GTx and the actual receiver PRx. Similarly, scaling or proportionality factors (b) can be used to scale a measurement TR as between the actual wireless power transmitter PTx and actual wireless power receiver PRx to be as between the actual power transmitter PTx and the golden wireless power receiver GRx. Thus, as depicted in the equation below diagram 301, a gain relating to the wireless power transmitter coil g_{coil,TX} can be computed to a value that can be stored on the wireless power transmitter.

As illustrated in diagram 302 of FIG. 3, wireless power receiver scaling can proceed similarly. More specifically, various gain factors g may be computed for various parameters based on parings between a “golden” or “reference” wireless power transmitter GTx and wireless power receiver GRx and the actual wireless power transmitter PTx and wireless power receiver PRx. More specifically, scaling or proportionality factors (a) can be used to scale a measurement GG as between the golden or reference transmitter GTx and golden or reference receiver GRx so as to correspond to a measurement TG as between the golden receiver GRx and the actual transmitter PTx. Similarly, scaling or proportionality factors (b) can be used to scale a measurement TR as between the actual wireless power transmitter PTx and actual wireless power receiver PRx to be as between the actual power receiver PRx and the golden wireless power transmitter GTx. Thus, as depicted in the equation below diagram 302, a gain relating to the wireless power receiver coil g_{coil,TX} can be computed to a value that can be provided to the wireless power receiver and/or can be stored on the wireless power transmitter. Similarly gain parameters for ecosystem scaling can similarly be computed for the coefficients described above relating to friendly metal loss estimation based on one or more parameters such as transmitter current (g_{FM,ITX}), rectifier current (g_{FM,IRECT}), and/or rectifier voltage (g_{FM,VRECT}). These gain parameters for ecosystem scaling can be computed by and remain on the wireless power transmitter, although in some embodiments they may also be computed by and/or provided to the wireless power receiver.

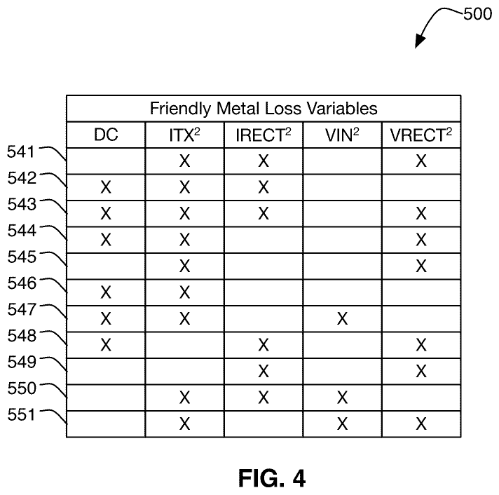

FIG. 4 illustrates a table 500 depicting some combinations of monitorable parameters in a wireless power transfer system that can be used for friendly metal loss estimation. The parameters that can be used can include a DC modeling parameter (DC), transmitter current (squared) ITX², rectifier current (squared) IRECT², inverter input voltage (Vin), and rectifier voltage (squared) VRECT². The description above focused on the combination depicted in row 541 of table 500, using transmitter current squared, rectifier current squared, and rectifier voltage squared. However, inventors have experimented with models incorporating 2-4 of the variables in various combinations as depicted in rows 542-551 and have observed differing degrees of accuracy for various models depending on the particular implementation. Thus, for a given implementation, it may be desirable to employ one or more models incorporating different combinations of such variables as appropriate to a given application. In any case, model equations can be selected and corresponding coefficients can fit based on power transfer measurements as described above and in the incorporated applications/appendices.

In some cases, a friendly metal loss model may be based on measurements of transmitter current (squared) ITX², rectifier current (squared) IRECT², and rectifier voltage (squared) VRECT² because a model incorporating these parameters may provide for enhanced accuracy with respect to other models. However, in some cases, the ecosystem scaling coefficients discussed above may be unduly sensitive to the rectifier current measurement, which can cause either small changes in rectifier current or measurement errors associated with the rectifier current measurement to significantly perturb the derived coefficients for the friendly metal loss model. Thus, in some cases, it may be desirable to determine the ecosystem scaling coefficients without the rectifier current (I_{RECT}) term, even though the model may otherwise use this term for improved friendly metal loss estimation accuracy.

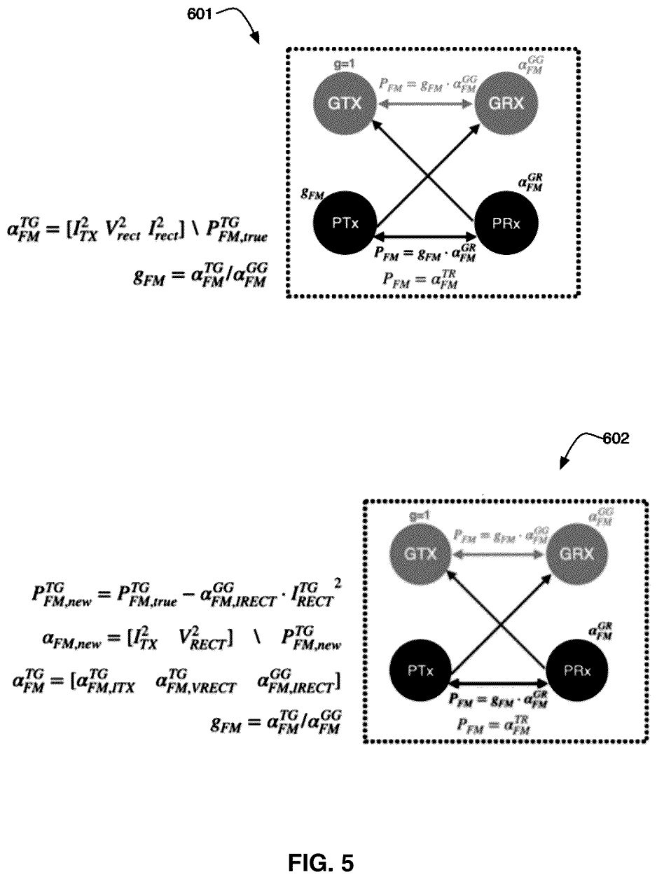

With reference to FIG. 5, an ecosystem scaling technique 601 can be one in which the ecosystem scaling model incorporates transmitter current (squared) ITX², rectifier current (squared) IRECT², and rectifier voltage (squared) VRECT². The golden or reference transmitter GTX and the “golden” or reference receiver GRx can have associated friendly metal losses given by:

$${P}_{FM} = {g}_{FM} \cdot {α}_{FM}^{G G} \times [ {I}_{TX}^{2} {V}_{rect}^{2} {I}_{rect}^{2} ]$$

where P_{FM} is the friendly metal loss, g_{FM} is a gain parameter computed as described above based on the full range of parameters, e.g., transmitter current (squared) ITX², rectifier current (squared) IRECT², and rectifier voltage (squared) VRECT², and

$${α}_{FM}^{G G}$$

is an ecosystem scaling constant corresponding to the friendly metal losses corresponding to the golden/golden or reference/reference transmitter-receiver pair. A given transmitter PTx and/or a given receiver PRx can have corresponding friendly metal losses in the same regime determined with reference to associated coefficients g_{FM} and

$${α}_{FM}^{GR} ,$$

where g_{FM} is as described above and

$${α}_{FM}^{GR}$$

is a proportionality constant associated with measurements made using the golden or reference receiver GTx and the given receiver GRx. The friendly metal losses as between the given transmitter PTx and the given receiver PRx are thus given by:

$${α}_{FM}^{TR} = {g}_{FM} \cdot {α}_{FM}^{GR}$$

with the parameters as described above. More specifically,

$${α}_{FM}^{TR}$$

is determined with respect to the full range of variables, e.g., transmitter current (squared) ITX², rectifier current (squared) IRECT², and rectifier voltage (squared) VRECT², and the estimated friendly metal power loss P_{FM} is based on the “true” friendly metal losses, i.e., incorporating the transmitter current (squared) ITX² term.

As described above, if the scaling parameters are determined with reference to the full range of parameters, e.g., transmitter current (squared) ITX², rectifier current (squared) IRECT², and rectifier voltage (squared) VRECT², undesired errors may arise in some cases due to sensitivity of the analysis to a particular term, for example, the rectifier current (squared) IRECT² term. Thus, an ecosystem scaling technique 602 can be one in which the ecosystem scaling coefficients are determined with reference to a subset of the parameters used in the friendly metal loss estimation model. As one example, the friendly metal loss estimation technique can be based on transmitter current (squared) ITX², rectifier current (squared) IRECT², and rectifier voltage (squared) VRECT², while the ecosystem scaling parameters can be determined with reference to only a subset of these parameters, e.g., transmitter current (squared) ITX² and rectifier voltage (squared) VRECT². This can allow for improved accuracy in cases where the ecosystem scaling parameters exhibit undesirably high sensitivity to a particular parameter, e.g., rectifier current (squared) IRECT². However, it should be understood that in some applications, different subsets may be used depending on the sensitivities of a particular system or implementation.

Thus, with further reference to ecosystem scaling technique 602, a second friendly metal loss estimate can be given by:

$${P}_{FM , new}^{TG} = {P}_{FM , true}^{T G} - {α}_{FM , IRECT}^{G G} \cdot {( {I}_{RECT}^{TG} )}^{2}$$

where

$${P}_{FM , true}^{TG}$$

is the “true” friendly metal loss based on the full range of parameters,

$${α}_{FM , IRECT}^{G G}$$

is a coefficient based on the rectifier current and

$${I}_{RECT}^{TG}$$

is the measured rectifier current.

$${P}_{FM , new}^{TG}$$

is thus a friendly metal power loss with the impact of the rectifier current subtracted. Put another way, the “new” friendly metal loss is the “true” friendly metal loss with the effect of (in this case) the rectifier current IRECT removed. New fit coefficients for the friendly metal loss can then be determined with respect to the non-omitted parameters, e.g., transmitter current (squared) ITX² and rectifier voltage (squared) VRECT². This is represented by the expression:

$${α}_{FM , new} = [ \begin{matrix}{I}_{TX}^{2} & {V}_{RECT}^{2}\end{matrix} ] ∖ {P}_{FM , new}^{TG}$$

where α_{FM,new} is the fit coefficient based on the subset of parameters, e.g.,

$${I}_{TX}^{2} and {V}_{RECT}^{2} .$$

Thereafter, the scaling parameter set can be modified to include an IRECT term based on the golden-golden/reference-reference transmitter-receiver pair. This is represented by:

$${α}_{FM}^{TG} = [ \begin{matrix}{α}_{FM , ITX}^{TG} & {α}_{FM , VRECT}^{TG} & {α}_{FM , IRECT}^{GG}\end{matrix} ]$$

where

$${α}_{FM , ITX}^{TG} and {α}_{FM , VRECT}^{TG}$$

are friendly metal loss parameters scaled by the ecosystem scaling parameters and

$${α}_{FM , IRECT}^{GG}$$

is a friendly metal loss parameter that is not scaled by the ecosystem scaling measurements. Put another way, the ecosystem scaling gain g_{FM} is set to 1 for the rectifier current IRECT term. As described above, in some implementations this could be an alternative parameter to which the ecosystem scaling has undesirable sensitivity.

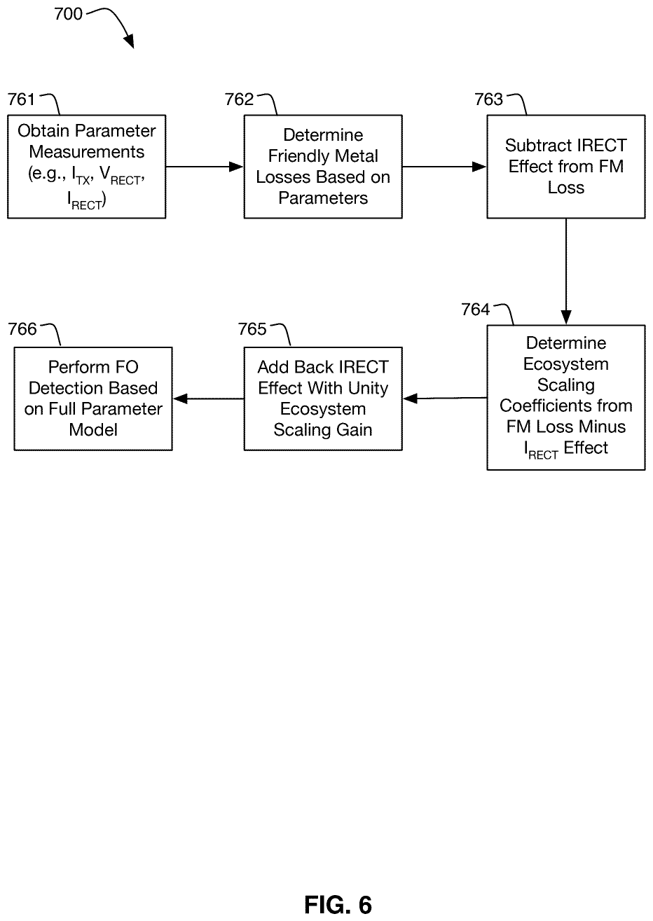

FIG. 6 depicts a flow chart 700 illustrating foreign object detection using the ecosystem scaling technique described above. The technique can be performed by control circuitry of the wireless power transmitter (PTx) as described above. In some applications, all or part of the technique could be performed by the wireless power receiver control circuitry. In block 761, the device (e.g., the control circuitry of a wireless power transmitter) can obtain parameter measurements for a friendly metal loss metal. As one example, this can include transmitter current (squared) ITX², rectifier current (squared) IRECT², and rectifier voltage (squared) VRECT². In this example, transmitter current can be determined directly by the transmitter control circuitry and the rectifier current and rectifier voltage can be received by in-band our out-of-band communication from a wireless power receiver. In block 762, the transmitter can determine friendly metal losses based on the measurements and coefficients derived from a golden or reference transmitter-receiver pairing.

In block 763, the effect of one or more parameters can be subtracted from the determined friendly metal losses. Such one or more parameters can be one or more parameters to which the ecosystem scaling model has undesirable sensitivity. In block 764, the ecosystem scaling coefficients can be determined based on the modified friendly metal losses with the effect of the omitted parameter(s) removed. In block 765, the effect of the rectifier current term (or other omitted term) can be added back into the model based on the original golden-golden (reference-reference) pairing that was subtracted in block 763. This effectively causes the ecosystem scaling gain with respect to the IRECT term (or other term omitted for sensitivity reasons) to be equal to 1, ensuring that small changes or errors in measurement of this term do not unduly perturb the determined coefficients for the friendly metal loss model. Then, in block 766, foreign object detection can be performed based on friendly metal loss modeling and ecosystem scaling performed as described above.

Described above are various features and embodiments relating to improving friendly metal loss estimation to improve wireless power transfer in wireless power transfer systems. Such arrangements may be used in a variety of applications but may be particularly advantageous when used in conjunction with electronic devices such as mobile phones, tablet computers, laptop or notebook computers, and accessories, such as wireless headphones, styluses, etc. Additionally, although numerous specific features and various embodiments have been described, it is to be understood that, unless otherwise noted as being mutually exclusive, the various features and embodiments may be combined various permutations in a particular implementation. Thus, the various embodiments described above are provided by way of illustration only and should not be constructed to limit the scope of the disclosure. Various modifications and changes can be made to the principles and embodiments herein without departing from the scope of the disclosure and without departing from the scope of the claims.

The foregoing describes exemplary embodiments of wireless power transfer systems that are able to transmit certain information between the PTx and PRx in the system. The present disclosure contemplates this passage of information improves the devices' ability to provide wireless power signals to each other in an efficient manner to facilitate battery charging, such as by sharing of the devices' power handling capabilities with one another. Entities implementing the present technology should take care to ensure that, to the extent any sensitive information is used in particular implementations, that well-established privacy policies and/or privacy practices are complied with. In particular, such entities would be expected to implement and consistently apply privacy practices that are generally recognized as meeting or exceeding industry or governmental requirements for maintaining the privacy of users. Implementers should inform users where personally identifiable information is expected to be transmitted in a wireless power transfer system and allow users to “opt in” or “opt out” of participation. For instance, such information may be presented to the user when they place a device onto a power transmitter, if the power transmitter is configured to poll for sensitive information from the power receiver.

1. A method performed by control circuitry of a wireless power transmitter or a wireless power receiver for estimating friendly metal losses associated with wireless power transfer from the wireless power transmitter to a wireless power receiver, the method comprising:
obtaining one or more circuit parameters including one or more voltage or current measurements of the wireless power transmitter or the wireless power receiver;
determining friendly metal losses based on the one or more circuit parameters;
subtracting an effect of at least one of the one or more voltage or current measurements from the determined friendly metal losses to derive a modified friendly metal loss;
determining one or more ecosystem scaling parameters based on the modified friendly metal loss;
adding the effect of at least one of the one or more voltage or current measurements from the determined friendly metal losses to derive one or more friendly metal loss coefficients; and
performing foreign object detection based on a friendly metal loss model including the derived one or more friendly metal loss coefficients.

2. The method of claim 1 wherein the one or more ecosystem scaling parameters are based one or more of:
operation of the wireless power transmitter with a reference wireless power receiver;
operation of the wireless power receiver with a reference wireless power transmitter; and
operation of the reference wireless power transmitter with the reference wireless power receiver.

3. The method of claim 1 wherein the one or more circuit parameters include a rectifier voltage of the wireless power receiver, a rectifier current of the wireless power receiver, and an inverter voltage of the wireless power transmitter.

4. The method of claim 3 wherein subtracting the effect of at least one of the one or more voltage or current measurements from the determined friendly metal losses to derive a modified friendly metal loss includes subtracting an effect of the rectifier current.

5. The method of claim 4 wherein the derived one or more friendly metal loss coefficients include a first coefficient relating to the rectifier current, a second coefficient relating to the rectifier voltage, and a third coefficient relating to the transmitter current.

6. The method of claim 5 wherein the friendly metal power loss model is of a form:
$${P}_{loss} = a \cdot {I}_{TX}^{2} + b \cdot {I}_{rect}^{2} + c \cdot {V}_{rect}^{2}$$
where b is the first coefficient relating to the rectifier current, c is the second coefficient relating to the rectifier voltage, and a is the third coefficient relating to transmitter current.

7. The method of claim 1 wherein the derived one or more friendly metal loss coefficients include a first coefficient relating to a rectifier current, a second coefficient relating to a rectifier voltage, and a third coefficient relating to the transmitter current.

8. The method of claim 7 wherein the friendly metal power loss model is of a form:
$${P}_{loss} = a \cdot {I}_{TX}^{2} + b \cdot {I}_{rect}^{2} + c \cdot {V}_{rect}^{2}$$
where b is the first coefficient relating to the rectifier current, c is the second coefficient relating to the rectifier voltage, and a is the third coefficient relating to the transmitter current.

9. A wireless power transmitter comprising:
a wireless power transmitter coil configured to magnetically couple to a wireless power receiver coil of a wireless power receiver to wirelessly transfer power to the wireless power receiver;
an inverter configured to receive input power and generate an output that drives the wireless power transmitter coil; and
controller and communication circuitry coupled to the inverter and the wireless power transmitter coil that controls the inverter to regulate wireless power transfer to the wireless power receiver, wherein the controller and communication circuitry estimates a friendly metal loss associated with wireless power transfer to the wireless power receiver by:
obtaining one or more circuit parameters including one or more voltage or current measurements of the wireless power transmitter or the wireless power receiver;
determining friendly metal losses based on the one or more circuit parameters;
subtracting an effect of at least one of the one or more voltage or current measurements from the determined friendly metal losses to derive a modified friendly metal loss;
determining one or more ecosystem scaling parameters based on the modified friendly metal loss;
adding the effect of at least one of the one or more voltage or current measurements from the determined friendly metal losses to derive one or more friendly metal loss coefficients; and
performing foreign object detection based on a friendly metal loss model including the derived one or more friendly metal loss coefficients.

10. The wireless power transmitter of claim 9 wherein the one or more ecosystem scaling parameters are based one or more of:
operation of the wireless power transmitter with a reference wireless power receiver;
operation of the wireless power receiver with a reference wireless power transmitter; and
operation of the reference wireless power transmitter with the reference wireless power receiver.

11. The wireless power transmitter of claim 9 wherein the one or more circuit parameters include a rectifier voltage of the wireless power receiver, a rectifier current of the wireless power receiver, and an inverter voltage of the wireless power transmitter.

12. The wireless power transmitter of claim 11 wherein subtracting the effect of at least one of the one or more voltage or current measurements from the determined friendly metal losses to derive a modified friendly metal loss includes subtracting an effect of the rectifier current.

13. The wireless power transmitter of claim 12 wherein the derived one or more friendly metal loss coefficients include a first coefficient relating to the rectifier current, a second coefficient relating to the rectifier voltage, and a third coefficient relating to the transmitter current.

14. The wireless power transmitter of claim 13 wherein the friendly metal power loss model is of a form:
$${P}_{loss} = a \cdot {I}_{TX}^{2} + b \cdot {I}_{rect}^{2} + c \cdot {V}_{rect}^{2}$$
where b is the first coefficient relating to the rectifier current, c is the second coefficient relating to the rectifier voltage, and a is the third coefficient relating to transmitter current.

15. The wireless power transmitter of claim 9 wherein the derived one or more friendly metal loss coefficients include a first coefficient relating to a rectifier current, a second coefficient relating to a rectifier voltage, and a third coefficient relating to the transmitter current.

16. The wireless power transmitter of claim 15 wherein the friendly metal power loss model is of a form:
$${P}_{loss} = a \cdot {I}_{TX}^{2} + b \cdot {I}_{rect}^{2} + c \cdot {V}_{rect}^{2}$$
where b is the first coefficient relating to the rectifier current, c is the second coefficient relating to the rectifier voltage, and a is the third coefficient relating to the transmitter current.

17. A wireless power receiver comprising:
a wireless power receiver coil configured to magnetically couple to a wireless power transmitter coil of a wireless power transmitter to wirelessly receive power from the wireless power receiver;
a rectifier configured to receive input power from the wireless power receiver coil and generate an output that delivers power to a load; and
controller and communication circuitry coupled to the rectifier and the wireless power receiver coil that controls the rectifier and estimates a friendly metal loss associated with wireless power transfer to the wireless power receiver by:
obtaining one or more circuit parameters including one or more voltage or current measurements of the wireless power transmitter or the wireless power receiver;
determining friendly metal losses based on the one or more circuit parameters;
subtracting an effect of at least one of the one or more voltage or current measurements from the determined friendly metal losses to derive a modified friendly metal loss;
determining one or more ecosystem scaling parameters based on the modified friendly metal loss;
adding the effect of at least one of the one or more voltage or current measurements from the determined friendly metal losses to derive one or more friendly metal loss coefficients; and
performing foreign object detection based on a friendly metal loss model including the derived one or more friendly metal loss coefficients.

18. The wireless power transmitter of claim 17 wherein subtracting the effect of at least one of the one or more voltage or current measurements from the determined friendly metal losses to derive a modified friendly metal loss includes subtracting an effect of the rectifier current.

19. The wireless power transmitter of claim 17 wherein the derived one or more friendly metal loss coefficients include a first coefficient relating to a rectifier current, a second coefficient relating to a rectifier voltage, and a third coefficient relating to the transmitter current.

20. The wireless power transmitter of claim 19 wherein the friendly metal power loss model is of a form:
$${P}_{loss} = a \cdot {I}_{TX}^{2} + b \cdot {I}_{rect}^{2} + c \cdot {V}_{rect}^{2}$$
where b is the first coefficient relating to the rectifier current, c is the second coefficient relating to the rectifier voltage, and a is the third coefficient relating to the transmitter current.
